(19) United States
(12) Patent Application Publication
(10) Pub. No.: US 2003/0086307 A1
(43) Pub. Date: May 8, 2003

(54) High-density information storage medium and method thereof

(75) Inventors: Kyung-Geun Lee, Gyeonggi-do (KR); In-sik Park, Gyeonggi-do (KR); Du-seop Yoon, Gyeonggi-do (KR)

Correspondence Address: STAAS & HALSEY LLP, 700 11TH STREET, NW, SUITE 500, WASHINGTON, DC, 20001, US

(73) Assignee: Samsung Electronics Co., Ltd., Suwon-City (KR)

(21) Appl. No.: 10/269,088

(22) Filed: Oct. 11, 2002

(30) Foreign Application Priority Data
Oct. 11, 2001 (KR) 2001-62671

(51) Int. Cl. G11C 7/00

(52) U.S. Cl. 365/200

(57) ABSTRACT

A high-density information storage medium includes a center hole, a clamping area, and a data area for recording user data, wherein when a wavelength of light radiated to record and/or reproduce information is λ, and when a numerical aperture of an objective lens to form a light spot of a predetermined size on a recording surface is NA, a ratio of {λ/NA} to a track pitch is 1.45 or less. The high-density information storage medium has favorable noise characteristics and a large serve margin while having a desired amount of a storage capacity.

### CROSS-REFERENCE TO RELATED APPLICATIONS

This application claims the benefit of Korean Patent Application No. 2001-62671, filed Oct. 11, 2001, in the Korean Intellectual Property Office, the disclosure of which is incorporated herein by reference.

### BACKGROUND OF THE INVENTION

1. Field of the Invention

The present invention relates to a high-density information storage medium, and more particularly, to a high-density information storage medium with an improved structure capable of reducing noise.

2. Description of the Related Art

As is well known, to record information on and/or reproduce information from an information storage medium, such as a digital versatile disc (DVD), light of a 650-nm wavelength and an objective lens having a numerical aperture (NA) of 0.6 (0.65 for a recordable DVD) are used in an optical recording and reproducing apparatus. When the DVD has a diameter of 120 mm and a track pitch of 0.74, a storage capacity of each side of the DVD reaches about 4.7 GB.

Accordingly, the DVD is insufficient to record moving picture information of a high-definition level. This is because an amount of the storage capacity greater than 20 GB is required for each side to record, for example, 135-minute moving picture information in the high-definition level.

To comply with the requirement for a high storage capacity, development and standardization of a high-density information storage medium, that is, a next-generation DVD (so-called high-definition (HD)-DVD)) having a narrower track, which uses blue-violet light having a shorter wavelength than red light and the objective lens having the NA of 0.6 or greater, are being promoted.

When light of a 405-nm wavelength and the objective lens having the NA of 0.85 are used in the optical recording and reproducing apparatus, the high-density information storage medium having the track pitch of 0.32 μm may have the storage capacity of 20 GB or greater.

The storage capacity of the information storage medium depends on a size (diameter) of a light spot formed on a recording surface of the high-density information storage medium and its track pitch. The size of the light spot is proportional to a wavelength λ of a light source and is inversely proportional to the NA of the objective lens. That is, {λ/NA} is proportional to the light spot size.

As shown in Table 1, the DVD having a track pitch TP of 0.74 μm has been standardized such that a ratio of {λ/NA} to the track pitch TP becomes about 1.46. In the DVD having the ratio of 1.46, noise characteristics occurring due to an inherent structure of the DVD are improved. When the high-density information storage medium, which uses light of the 405-nm wavelength and the objective lens of the NA of 0.85, has the track pitch TP of 0.32 μm, the ratio of {λ/NA} to the track pitch TP is 1.49, which is similar to that of the DVD.

TABLE 1

| | | High-Density Information |
|---|---|---|
| | DVD having | Storage Medium |
| | TP = 0.74 μm | having TP = 0.32 μm |
| Wavelength (λ) | 650 nm | 405 nm |
| Numerical Aperture (NA) | 0.60 | 0.85 |
| {λ/NA}/TP | 1.46 | 1.49 |

When the high-density information storage medium has the track pitch TP of 0.325 μm, the ratio of {λ/NA} to the track pitch TP is almost equal to that of the DVD. Therefore, in a technical field of the optical information storage, the high-density information storage medium requires the use of light of the 405-nm wavelength and the objective lens of the NA of 0.85 and to have the track pitch TP of about 0.32 μm.

A structure of the information storage medium, such as tracks and grooves, acts as a noise source generating signal noises when a reproduction signal and/or a tracking error signal are detected from the information storage medium. Mostly, the signal noises occurring from the grooves are from a groove wall formed during mastering of the information storage medium in a manufacturing process. Since it is impossible to form a completely smooth groove wall during mastering the information storage medium, the signal noises are produced from the groove wall. The smaller the track pitch, the greater the noise from the groove wall.

In the technical field, a blue-violet semiconductor laser, which can be used as a blue-violet light source for an optical pickup, is known to have poor noise characteristics, compared to a red semiconductor laser used as a light source for the DVD.

In view of the noise characteristics of the blue-violet light source, when designing the high-density information storage medium using blue-violet light, special attention is required to reduce the generation of the signal noises due to the medium structure and to achieve a desired amount of the storage capacity.

### SUMMARY OF THE INVENTION

To solve the above and other problems, it is an object of the present invention to provide a high-density information storage medium with an improved structure, which has a desired high storage capacity and is capable of effectively reducing noises generated due to a medium structure.

Additional objects and advantageous of the invention will be set forth in part in the description which follows and, in part, will be obvious from the description, or may be learned by practice of the invention.

To achieve the above and other objects of the present invention, there is provided a high-density information storage medium including a center hole, a clamping area, and a data area for recording user data. When a wavelength of light radiated to record and/or reproduce information is λ and a numerical aperture of an objective lens to form a light spot of a predetermined size on a recording surface is NA, a ratio of {λ/NA} to a track pitch is 1.45 or less.

According to an aspect of the present invention, the data area has a start radius of 24 mm or less. In the high-density information storage medium, it is possible that a land track and a groove track are formed, and that at least one of the land track and the groove track is a recording track. In this case, the ratio of {λ/NA} to a width of one of the land track and the groove track is from 1.5 to 3.0.

According to another aspect of the present invention, the track pitch is greater than 3.2 μm. It is possible that the clamping area is located in a range of 20-29 mm of a diameter of the high-density information storage medium.

### BRIEF DESCRIPTION OF THE DRAWINGS

These and other objects and advantageous of the invention will become apparent and more readily appreciated from the following description of the preferred embodiments, taken in conjunction with the accompanying drawings of which:

FIG. 1 is a perspective view of a high-density information storage medium according to an embodiment of the present invention;

FIG. 2 is a cross-sectional view of the high-density information storage medium of FIG. 1;

FIG. 3 shows a plan view of a light spot focused on a portion of the high-density information storage medium of FIG. 1;

FIG. 4 is a graph showing a relationship between a storage capacity and a track pitch under conditions of Table 3;

FIGS. 5A and 5B show push-pull signals detected from 405-nm light reflected by a recording surface of optical information storage media with a track pitch of 0.32 μm and 0.35 μm, respectively, after being focused by an objective lens of an NA of 0.85;

FIG. 6 shows a plan view of a light spot focused on a portion of the high-density information storage medium according to another embodiment of the present invention;

FIGS. 7A and 7B are graphs showing a measuring displacement with respect to variations of a clamping area when the high-density information storage medium is rotated at 3600 rpm and 6000 rpm, respectively, without applying an external excitation to the high-density information storage medium;

FIGS. 8A and 8B are graphs showing a measuring acceleration with respect to variations of the claming area when the high-density information storage medium is rotated at 3600 rpm and 6000 rpm, respectively, without applying the external excitation to the high-density information storage medium;

FIGS. 9A and 9B are graphs showing a measuring FRF RMS at a radial position of 56.5 mm on the high-density information storage medium when the high-density information storage medium is rotated at 3600 rpm and 6000 rpm, respectively, while subjected to a sine sweep of the external excitation of 5-200 Hz; and

FIGS. 10A and 10B are graphs showing a measuring FRF {Aout/Ain} at the radial position of 56.5 mm on the high-density information storage medium when the high-density information storage medium is rotated at 3600 rpm and 6000 rpm, respectively, while subjected to the sine sweep of the external excitation of 5-200 Hz.

### DETAILED DESCRIPTION OF THE PREFERRED EMBODIMENTS

Reference will now be made in detail to the present preferred embodiments of the present invention, examples of which are illustrated in the accompanying drawings, wherein like reference numerals refer to the like elements throughout. The embodiments are described in order to explain the present invention by referring to the figures.

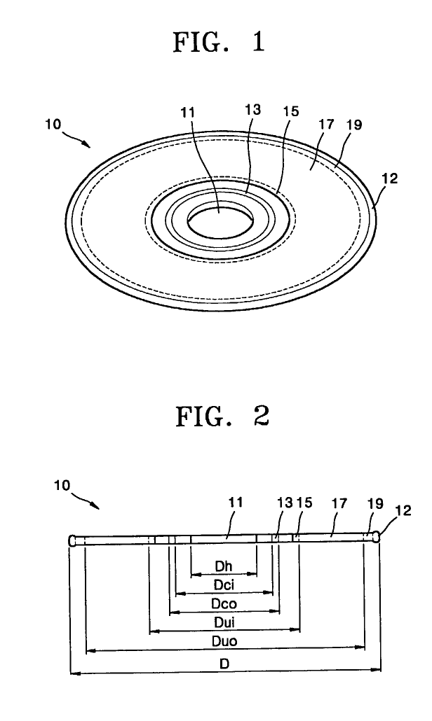

Referring to FIGS. 1 and 2, a high-density information storage medium (optical disc) 10 according to an embodiment of the present invention includes a center hole 11, a clamping area 13 to which a clamping force is applied, and a data area 17 for recording user data. A lead-in area 15 and a lead-out area 19 are disposed inside and outside the data area 17, respectively. Data is recorded on a recording area starting from the lead-in area 15 toward an outside in a radial direction of the high-density information storage medium.

The center hole 11 receives and is coupled to a projection portion of a turntable installed in a driving unit such that the information storage medium 10 is loaded on the turntable. It is possible that the center hole 11 has a diameter to be compatible with conventional information storage media. For example, the center hole 11 may have a diameter of 15 mm equal to that of a compact disc (CD) and a digital versatile disc (DVD). The clamping area 13 is pushed close to the turntable by a clamping member installed in the driving unit and is subject to the clamping force. Here, although the clamping area 13 is described only as a portion contacting the turntable when pushed by the clamping member, it will be appreciated that a definition of the clamping area 13 is not limited to only the portion contacting the turntable. For example, from an outer circumference of the center hole 11 to an outer diameter of the portion being in contact with the turntable can be defined as the clamping area.

Since the turntable loading the information storage medium, an information storage medium rotary driving apparatus (driving unit) including a spindle motor rotating the turntable, a recording apparatus recording the user data in the data area of the information storage medium using a laser diode, and the clamping apparatus applying the clamping force to the information storage medium are included in a storage medium recording and reproducing apparatus, which is well known in this field, detailed descriptions and illustrations thereon will be omitted. However, the storage medium recording and reproducing apparatus can be modified and adjusted to record/reproduce data on/from the high-density information storage medium 10.

In the high-density information storage medium 10 shown in FIGS. 1 and 2, a stacking ring portion is formed between the clamping area 13 and the lead-in area 15 to prevent an area including the lead-in area 15, the data area 17, and the lead-out area 19 from contacting other high-density information storage media when a number of the information storage media are stacked upon one another after a molding process, and the contact between the information storage media would cause an error on data stored in the information storage media. In FIG. 1, a rim portion 12 is formed around the lead-out area 19. An outer diameter of the rim portion 12 corresponds to the diameter of the high-density information storage medium 10. For example, when the high-density information storage medium 10 has a diameter of 120 mm, the outer diameter of the rim portion 12 is 120 mm.

In FIG. 2, Dh denotes a diameter of the center hole 11, Dci and Dco denote inner and outer diameters of the claming area 13, respectively, and Dui and Duo denote inner and outer diameters of the data area 117, respectively, and D denotes the diameter of the high-density information storage medium 10.

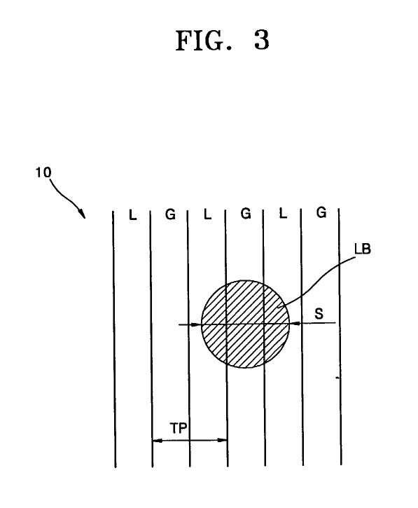

As described above, the high-density information storage medium 10 is divided into a plurality of areas having their own function and extending from its center in the radial direction. Tracks are formed over the lead-in area 15, the data area 17, and the lead-out area 19. Referring to FIG. 3, the high-density information storage medium 10 includes a land track G and a groove track L. It is possible that the high-density information storage medium 10 has a structure to record information in at least one of the groove track G and the land track L, and more preferably, only in the groove track G (i.e., groove-only type). When the information storage medium has both the groove track G and the land track L as shown in FIG. 3, a track pitch TP is a sum of widths of the groove track G and land track L.

When a wavelength of light emitted to record and/or reproduce information is λ, and when a numerical aperture of an objective lens to focus the light to form a light spot LB of a predetermined diameter S on a recording surface is NA, in the high-density information storage medium 10, a ratio of {λ/NA} to the track pitch TP is 1.45 or less. As a result, generation of noises occurring due to an inherent disc structure, such as the groove wall, of the high-density information storage medium 10 formed during mastering the high-density information storage medium 10 in a manufacturing process can be reduced.

Here, a size of the light spot LB is expressed as a formula (1) below:

S∝λ/NA (1)

Table 2 shows the ratio of {λ/NA} to the track pitch TP with respect to a track pitch variation in the high-density information storage medium 10 compared with the DVD when light of a 405-nm wavelength and the objective lens having the NA of 0.85 are used to record and/or reproduce information on/from the high-density information storage medium 10.

TABLE 2

| | | High-Density | |
|---|---|---|---|
| | | Information | Remarks |
| | DVD | Storage Medium | (track pitch TP) |
| Wavelength (λ) | 650 nm | 405 nm | — |
| Numerical Aperture (NA) | 0.60 | 0.85 | — |
| {λ/NA}/TP1 | 1.46 | 1.49 | TP1 = 0.32 μm |
| {λ/NA}/TP2 | — | 1.36 | TP2 = 0.35 μm |

In Table 2, 1.46 results as the ratio of {λ/NA} to the track pitch TP when the DVD has the track pitch of 0.74 μm.

With regard to the high-density information storage medium 10, under conditions of the wavelength and the NA of Table 2, the ratio of {λ/NA} to the track pitch TP is 1.49 when the track pitch TP1 is 0.32 μm. When the high-density information storage medium 10 has the track pitch TP2 of 0.35 μm, the ratio of {λ/NA} to the track pitch TP becomes about 1.36, which is less than 1.45.

As the track pitch TP becomes greater, the storage capacity per unit area decreases. Therefore, to ensure the same storage capacity as when the track pitch TP is relatively narrow, there is a need to increase the area of the data area 17 when the information storage medium 10 has a greater track pitch TP. Since the information storage medium has a limited diameter D, a start radius, i.e., the inner diameter Dui of the data area 17, from which the data area 17 starts, can be reduced to increase the area of the data area 17.

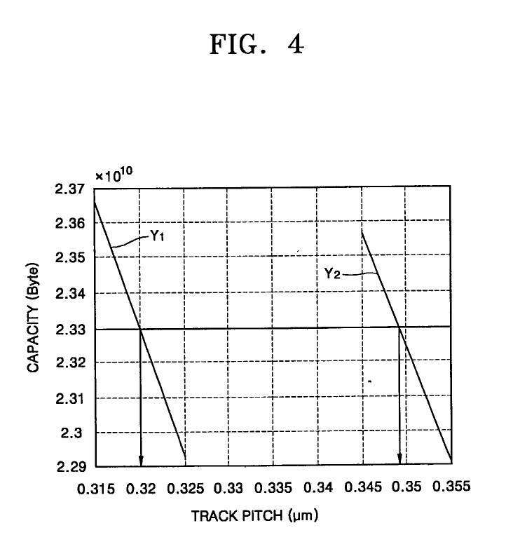

FIG. 4 is a graph showing a relationship between the storage capacity and the track pitch TP using conditions of Table 3. In Table 3 as shown below, ‘Efficiency’ means an actual percentage of the data area 17 where the user data is recorded, and ‘Modulation (1-7)’ means that the user data is recorded using ‘0’ and ‘1’, in which a minimum number of zeros between successive ‘1’s is 1 and a maximum number of zeros between successive ‘1’s is 7.

TABLE 3

| Storage Capacity | 23.3 GB |
|---|---|
| Modulation | (1-7) |
| Minimum Mark Length | 0.16 μm |
| Efficiency | 81.738% |

In FIG. 4, graphs Y1 and Y2 show relationships between the storage capacity and the track pitch TP when the start radius of the data area 17 is 24 mm and 18 mm, respectively, when other conditions, that is, the outer diameter Duo (see FIG. 2) of the data area 17, the diameter D of the information storage medium, the minimum mark length, and other data recording scheme are the same. Since the storage capacity and the track pitch TP have an inversely proportional relationship, the graphs Y1 and Y2 are linear. As shown in FIG. 4, when an amount of the storage capacity of 23.3 GB is attained with the track pitch TP of 0.32 μm, the inner diameter Dui of the data area 17 of 48 mm, and the conditions of Table 3, the same storage capacity can be achieved with a new track pitch of 0.349 μm and a new start radius of 18 mm in the data area 17.

To maintain the storage capacity with a larger track pitch than a conventional track pitch, there is a need to increase the area of the data area 17. For example, when the track pitch TP is increased from 0.32 μm to 0.349 μm, the data area 17 can be increased by reducing the start radius of the data area 17 from 24 mm to 18 mm.

To satisfy requirements for the larger track pitch and the same amount of the storage capacity, in the high-density information storage medium 10, the start radius of the data area 17 is determined to be 24 mm or less, and preferably, about 18 mm.

When the ratio of {λ/NA} to the track pitch TP is reduced as in the high-density information storage medium 10, noises occurring due to the medium structure, such as the groove wall, decrease, and amplitude of a tracking error signal increases. Accordingly, a large servo margin is required during a servo control.

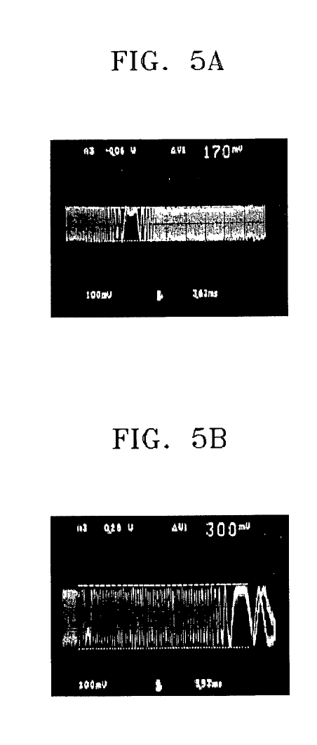

FIGS. 5A and 5B show tracking error signals, i.e., push-pull signals, detected from the 405-nm light reflected by the recording surface of the information storage media with the track pitch TP of 0.32 μm and 0.35 μm, respectively, after being focused by the objective lens having the NA of 0.85. As is apparent from FIGS. 5A and 5B, the amplitude of the push-pull signal when the track pitch TP is 0.35 μm, is 1.8 times greater than that of the push-pull signal when the track pitch TP is 0.32 μm. Here, the push-pull signals shown in FIGS. 5A and 5B are detected from the information storage media where the land track L and groove track G have the same width.

Therefore, it is possible that the high-density information storage medium 10 has the track pitch TP greater than 0.32 μm to ensure the sufficiently large servo margin in the servo control.

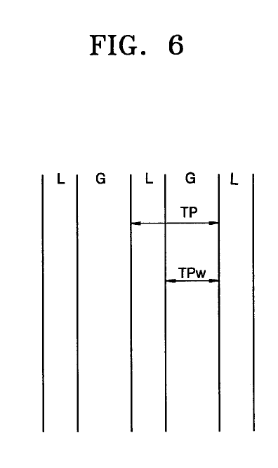

For a compatibility with a reproduction-only ROM drive, the high-density information storage medium 10 according to another embodiment of the present invention may have a structure recording information on one of the groove track G and the land track L. FIG. 6 shows a constant total track pitch TP, and it is possible that a width TPw of a recording track, for example, the groove track G, is increased whereas a width of a non-recording track, for example, the land track L, is reduced. Since the width TPw of the groove track G is not equal to that of the land track L as shown in FIG. 6, the amplitude of the push-pull signal is reduced compared to when the groove track G and the land track L have the same width. However, due to the increased total track pitch TP of FIG. 6, the amplitude of the push-pull signal can be increased compared to when the land track L and the groove track G have the same width, and when the track pitch TP is relatively narrow. Therefore, the high-density optical disk 10 is required to have the sufficiently large servo margin even when it has the structure of different track widths, as shown in FIG. 6. Since the recording track, for example, the groove track G, has the sufficiently large width TPw, the noise characteristics from the recording track wall are improved.

In the high-density information storage medium 10 according to an aspect of the present invention, a ratio of {λ/NA} to the width TPw of the recording track (groove track G or land track L) is from about 1.5 to about 3.0.

When a start point of the data area 17 is moved inward with respect to the high-density information storage medium 10 and toward the center hole 11 so as to maintain the storage capacity with the large track pitch TP of FIG. 6, it is necessary to move the outer diameter Dco of the clamping area 13 toward the center hole 11 and inward with respect to the high-density information storage medium 10 and to reduce a width of the clamping area 13 in the radial direction. Additionally, the inner diameter Dci of the clamping area 13 can be moved inward with respect to the high-density information storage medium 10 and toward the center hole 11.

As well known in the technical field, in the DVD, the data area 17 has the start radius of 24 mm (i.e., an inner diameter of the data area 17 of 48 mm), and the clamping area 13 has a diameter range of 23-33 mm, wherein a minimum inner diameter of the clamping area 13 is 23 mm, and a maximum outer diameter of the clamping area 13, indicated by Dco in FIG. 2, is 33 mm.

Compared with the DVD, in the high-density information storage medium 10, the inner diameter of the clamping area 13 can be determined to be smaller than or equal to 23 mm. It is possible that the outer diameter Dco of the clamping area 13 is moved further inward the high-density information storage medium 10 compared to that of the DVD. For example, the clamping area 13 of the high-density information storage medium 10 may have a diameter range of 20-29 mm.

Here, the outer diameter Dco of the clamping area 13 is moved inward the high-density information storage medium 10 to maintain and improve the recording and/or reproduction characteristics of the high-density information storage medium 10.

Hereinafter, dynamic characteristics of the high-density information storage medium 10 when the outer diameter of the clamping area 13 is inwardly moved will be described.

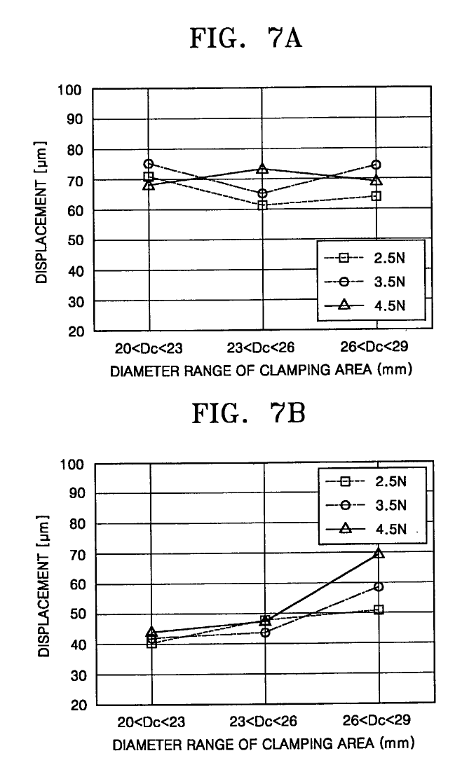

FIGS. 7A and 7B, FIGS. 8A and 8B, FIGS. 9A and 9B, and FIGS. 10A and 10B show results of measuring the dynamic characteristics of the high-density information storage medium 10 when the clamping area 13 is inwardly moved to have the diameter range of 26<Dc<29, 23<Dc<26, and 20<Dc<23 in millimeters. In this measurement, the clamping force was determined not to cause a slippage or a separation of the high-density information storage medium 10 rotating at a test rate.

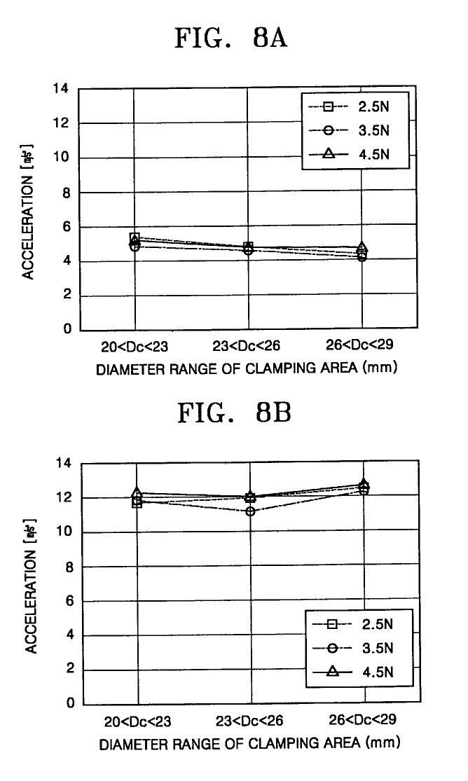

FIGS. 7A and 7B and FIGS. 8A and 8B show the results of measuring a displacement and acceleration with respect to diameter variations of the clamping area 13 when no external excitation (no external force causing a vibration of the high-density information storage medium 10) is applied to the high-density information storage medium 10 or the driving unit. The results of the acceleration shown in FIGS. 8A and 8B were obtained by differentiating the displacement results of FIGS. 7A and 7B twice. The results of FIGS. 7A and 8A are obtained when the high-density information storage medium 10 was rotated at 3600 RPM (60 Hz). The results of FIGS. 7B and 8B are obtained when the information storage medium was rotated at 6000 RPM (100 Hz).

In the technical field, a vibration tolerance of the high-density information storage medium 10 for a minimal servo gain is defined to be a first displacement up to 300 μm and a first acceleration up to 30 m/s² at a disc rotation speed of 60 Hz, which is equivalent to a rotation frequency of 60 Hz (3600 rpm) of a spindle motor of the driving unit, and the vibration tolerance is also defined to be a second displacement of 100 μm and a second acceleration of 40 m/s² at the disc rotation speed of 100 Hz, which is equivalent to the rotation frequency of 100 Hz (6000 rpm) of the spindle motor of the driving unit.

As is apparent from FIGS. 7A through 8B, in the absence of the external excitation, the reduction of the clamping area 13 to the diameter range of 20-29 mm does not greatly affect the dynamic characteristics of the high-density information storage medium 10. The resulting displacement and acceleration of the high-density information storage medium 10 are within the vibration tolerance for the minimum servo gain.

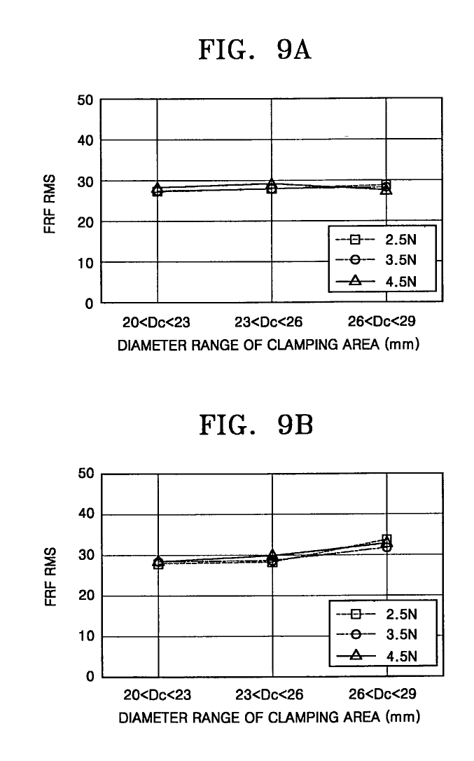

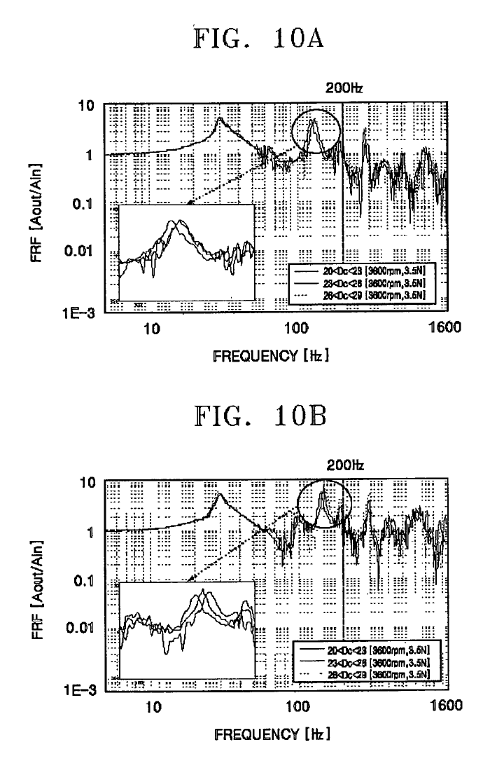

FIGS. 9A and 9B, and FIGS. 10A and 10B show the results of measuring a root mean square of a frequency response function (FRF RMS) and a ratio of an input to an input of the frequency response function (FRF{Aout/Ain}), respectively, at a radial position of 56.5 mm on the high-density information storage medium 10 when a sine sweep of the external excitation of 5-200 Hz is applied to the high-density information storage medium 10. The results of FIGS. 9A and 9B were obtained in the same conditions as for the results of FIGS. 7A and 7B, respectively, except for the application of the external excitation. FIGS. 10A and 10B show the results of measuring the FRF {Aout/Ain} according to an external excitation frequency when the high-density information storage medium 10 is rotated at 3600 rpm and 6000 rpm, respectively, while subjected to a clamping force of 3.5 N. Here, FRF means a relative amount of an amplitude variation with respect to an input frequency. The FRF{Aout/Ain} means a ratio of an output acceleration to an input acceleration, or a ratio of an output amplitude to an input amplitude of the FRF.

As is apparent from FIGS. 9A and 9B, the FRF RMS is little changed by the movement (shifting) of the clamping area 13 inward with respect to the high-density information storage medium 10. FIGS. 10A and 10B show that a peak value of the FRF{Aout/Ain} is little changed by the movement of the champing area 13. Therefore, such a degree of changes in the peak value is considered to be tolerable. A primary resonance frequency of the high-density information storage medium 10, when measured at the frequency at the peak value of the FRF, is also almost constant regardless of the movement of the clamping area 13. A slight shift of the peak, shown in FIGS. 10A and 10B, is due to the different disc rotation speeds.

From the results of FIGS. 9A through 10B, it is apparent that inwardly moving the clamping area 13 within the diameter range of 20-29 mm has little effect on the dynamic characteristics of the high-density information storage medium 10, even when the external excitation is applied to the high-density information storage medium 10.

According to the present invention, although the high-density information storage medium 10 has an increased track pitch, the storage capacity is not reduced since the start radius of the data area 17 is inwardly moved to have the inner diameter Dui of 24 mm or less, and accordingly the clamping area 13 is determined to be within a diameter range of 20-29 mm, and preferably, 23-26 mm or 20-23 mm. The high-density information storage medium 10 has much favorable dynamic characteristics.

The applicant has disclosed in U.S. Paten Application No. 60/323,099 filed Sep. 19, 2001 and Ser. No. 10/188,311 filed Jul. 3, 2002 corresponding to Korean Patent Application No. 2001-40052 filed on Jul. 5, 2001 that dynamic characteristics of an optical disc remain favorable when a clamping area is defined within the diameter range of 20-29 mm. This application describes effects of the inwardly moving the clamping area 13 on the dynamic characteristics of the optical disc, and thus explanation thereof will not be provided here.

In a high-density information storage medium according to the present invention as described above, when the wavelength of light radiated to record and/or reproduce information is λ and when the numerical aperture of the objective lens to focus the light spot (LB) of the diameter S on the recording surface is NA, the ratio of to the track pitch is defined to be 1.45 or less, and thus favorable noise characteristics and the large servo margin are ensured. Also, a desired high recording capacity can be maintained by inwardly moving the start radius of the data area.

While this invention has been particularly shown and described with reference to preferred embodiments thereof, it will be understood by those skilled in the art that various changes in form and details may be made therein without departing from the spirit and scope of the invention as defined by the appended claims and their equivalents.

What is claimed is:

1. A high-density information storage medium having a recording surface, comprising:
a center hole;
a clamping area; and
a data area for recording user data;
wherein when a wavelength of light radiated to record and/or reproduce information on/from the recording surface is λ, and when a numerical aperture of an objective lens to form a light spot of a predetermined size on the recording surface is NA, a ratio of {λ/NA} to a track pitch is 1.45 or less.

2. The high-density information storage medium of claim 1, wherein the data area has a start radius of 24 mm or less.

3. The high-density information storage medium of claim 2, wherein the data area has a start radius of about 18 mm.

4. The high-density information storage medium of claim 3, wherein the track pitch is greater than 3.2 μm.

5. The high-density information storage medium of claim 3, wherein the clamping area has a diameter range of 20-29 mm.

6. The high-density information storage medium of claim 2, further comprising:
a land track and a groove track, wherein at least one of the land track and the groove track is a recording track.

7. The high-density information storage medium of claim 6, wherein the one of the land track and the groove track has a width, and a ratio of {λ/NA} to the width of the one of the land track and the groove track is between 1.5 and 3.0 inclusive.

8. The high-density information storage medium of claim 2, wherein the track pitch is greater than 3.2 μm.

9. The high-density information storage medium of claim 2, wherein the clamping area has a diameter range of 20-29 mm.

10. The high-density information storage medium of claim 1, further comprising:
a land track and a groove track, wherein at least one of the land track and the groove track is a recording track.

11. The high-density information storage medium of claim 10, wherein the one of the land track and the groove track has a width, and a ratio of {λ/NA} to the width of the one of the land track and the groove track is between 1.5 and 3.0 inclusive.

12. The high-density information storage medium of claim 1, wherein the track pitch is greater than 3.2 μm.

13. The high-density information storage medium of claim 1, wherein the clamping area has a diameter range of 20-29 mm.

14. An information storage medium, comprising:
a data area having a land track having a land width, a groove track having a groove width greater than the land width of the land track, and a starting radius of 24 mm or less when a diameter of the information storage medium is 120 mm, wherein user data is recorded on the groove track.

15. The information storage medium of claim 14, wherein a sum of the land width and the groove width is greater than 3.2 μm.

16. An information storage medium, comprising:
a data area having a track pitch greater than 3.2 μm and a starting radius of 24 mm or less when a diameter of the high-density information storage medium is 120 mm,

17. The information storage medium of claim 16, wherein the data area comprises a land track and a groove track, and one of the land track and the groove track comprises:
a recording track, on which user data is recorded.

18. The information storage medium of claim 17, wherein the land track has a land width, and the groove track has a groove width greater than the land track when the groove track is the recording track.

19. The information storage medium of claim 17, wherein a sum of the land width and the groove width is the track pitch.

20. A method in an storage medium recording apparatus compatible with an information storage medium, the method comprising:
selecting one of a land track and a groove track of the information storage medium as a recording track, the one having a width greater than that of the other one of the land track and the groove track; and
recording user data on the recording track.

21. The method of claim 20, wherein a sum of the widths of the land track and the groove track is a track pitch, the storage medium recording apparatus comprises an objective lens and a laser diode generating light, and the recording of the user data comprises;
causing a ratio of {λ/NA} to the track pitch to be 1.45 or less where λ is a wavelength of the light radiated on the one of the land track and the groove track, and NA is a numeral aperture of the objective lens.

22. The method of claim 20, wherein the recording of the user data comprises;
clamping a clamping area having a diameter range between 20-29 mm.

23. The method of claim 22, wherein the recording of the user data comprises;
selecting a data area starting from an outer diameter of the clamping area in which to record the user data, the data area including the land track and the groove track.

23. The method of claim 20, wherein the recording of the user data comprises;
clamping a clamping area having a diameter range between 20-23 mm

24. The method of claim 23, wherein the recording of the user data comprises;
selecting a data area having a starting diameter of 24 mm, the data area including the land track and the groove track.

25. A storage medium recording apparatus compatible with an information storage medium, comprising:
a clamping unit clamping a clamp area of the information storage medium, the clamp area having a diameter range of 20-29 mm when the information storage medium has a diameter of 120 mm; and
a recording unit recording user data in a recording area of the information storage medium, the recording area having a starting radius of 24 mm or less in a radial direction of the information storage medium when the information storage medium has the diameter of 120 mm.

26. The storage medium recording apparatus of claim 25, wherein the claim area is between 20 mm and 23 mm inclusive.

27. The storage medium recording apparatus of claim 25, wherein the claim area is between 23 mm and 26 mm inclusive.

28. The storage medium recording apparatus of claim 25, wherein the information storage medium comprises a land track and a groove track having a width greater than that of the land track, and the recording unit selects the groove track and recording the user data on the groove track.

29. A storage medium recording apparatus compatible with first and second information storage media each having a diameter of 120 mm, comprising:
a clamping unit clamping a first clamp area having a first diameter range of 20-29 mm in the first information storage medium when the first storage medium is loaded, and clamping a second clamp area having a second diameter range greater than the first diameter range in the second information storage medium when the second storage medium is loaded; and
a recording unit recording user data in a first data area having a starting radius of 24 mm or less in the first information storage medium when the first information storage medium is loaded, and recording the user data in a second data area having a starting radius greater than 24 mm in the second information storage medium when the second information storage medium is loaded.

30. The storage medium recording apparatus of claim 29, wherein the first information storage medium comprises a first land track and a first groove track having a width greater that that of the land track, the second information storage medium comprises a second land track and a second groove track having the same width as the second land track, and the recording unit selecting the first groove track on which to record the user data when the first information storage medium is loaded, and recording the user data on one of the second land track and the second groove track.

31. A storage medium recording apparatus compatible with first and second information storage media, comprising:
a clamping unit clamping a first clamp area having a first diameter range in the first information storage medium when the first storage medium is loaded, and clamping a second clamp area having a second diameter range in the second information storage medium when the second storage medium is loaded, the second diameter range being greater than the first diameter range; and
a recording unit recording user data in a first data area having a first data area diameter range in the first information storage medium when the first information storage medium is loaded, and recording the user data in a second recording area having a second data area diameter range in the second information storage medium when the second information storage medium is loaded, the first data area diameter range being smaller than the second data area diameter range.
